(19) United States
(12) Patent Application Publication
(10) Pub. No.: US 2007/0187697 A1
(43) Pub. Date: Aug. 16, 2007

(54) Nitride based MQW light emitting diode having carrier supply layer

(76) Inventors: Liang-Wen Wu, Banciao City (TW); Fen-Ren Chien, Yonghe City (TW)

Correspondence Address: LIN & ASSOCIATES INTELLECTUAL PROPERTY, P.O. BOX 2339, SARATOGA, CA, 95070-0339, US

(21) Appl. No.: 11/355,121

(22) Filed: Feb. 15, 2006

(51) Int. Cl. H01L 33/00

(52) U.S. Cl. 257/79

(57) ABSTRACT

A MQW LED structure is provided herein, which contains a carrier supply layer joined to a side of the MQW light emitting layer to provide additional carriers for recombination and to avoid/reduce the use of impurity in the light emitting layer. The carrier supply layer contains multiple and interleaving well layers and barrier layers, each having a thickness of 5˜300 Å, with a total thickness of 1˜500 nm. The well layers and the barrier layers are both made of AlₚIn_{q}Ga_{1-p-q}N (p, q≧0, 0≦p+q≦1) compound semiconductor doped with Si or Ge, but with different compositions and with the barrier layers having a higher bandgap than that of the well layers. The carrier supply layer has an electron concentration of 1×10¹⁷˜5×10²¹/cm³.

### BACKGROUND OF THE INVENTION

1. Field of the Invention

The present invention generally relates to nitride-based multiple quantum-well light emitting diodes, and more particularly to a nitride-based multiple quantum-well light emitting diode having a carrier supply layer to provide additional carriers and to avoid/reduce the use of impurities in the light emitting layer.

2. The Prior Arts

To enhance the brightness of a gallium nitride-based (GaN-based) light emitting diode (LED), U.S. Pat. No. 5,578,839 teaches a LED structure having a light-emitting layer or an active layer made of InₓGa₁₋ₓN (0<x<1) compound semiconductor doped with n-typed impurity such as Si and/or with p-typed impurity such as Mg or Zn. The light emitting layer of the LED structure is sandwiched between a first clad layer made of an n-typed GaN-based compound semiconductor and a second clad layer made of a p-typed GaN-based compound semiconductor. The enhanced brightness of the LED structure is the result of having increased densities of carriers (i.e., electrons and holes) for recombination from the impurity doped in the light emitting layer.

In contrast, high-brightness LEDs using the multiple quantum-well (MQW) technique normally have undoped well layers in the light emitting layer. The light emitting layer of the MQW LEDs contains multiple well layers whose thickness is less then the deBroglie wavelength of the carriers in the semiconductor material. The electrons and holes are thereby confined in the well layers, achieving higher recombination efficiency. The well layers are normally undoped in that impurities in the well layers would introduce non-radiative recombination, causing the reduction of light emitting efficiency and the generation of extraneous heat. On the other hand, disclosed in Influence of Si doping on the Characteristics of InGaN—GaN Multiple Quantum-Well Blue Light Emitting Diode (IEEE Journal of Quantum Electronics, Vol. 38, No. 5, May 2002), Wu et al. suggests that the luminous intensity and operation voltage of InGaN—GaN MQW LEDs can be significantly improved by introducing Si doping in the GaN barrier layers of the MQW light emitting layer. However, the impurity density in the barrier layers should be maintained at an appropriate level otherwise the crystalline of the LED would be affected.

In other words, having impurities in the light emitting layer of a LED indeed contributes higher recombination efficiency but this improvement comes with a price to pay.

### SUMMARY OF THE INVENTION

Accordingly, the major objective of the present invention is to provide a nitride-based MQW LED structure to obviate the shortcomings of the prior arts.

A major aspect of present invention is to have a carrier supply layer joined to a side of an undoped MQW light emitting layer in the proposed LED structure. The carrier supply layer contains multiple and interleaving well layers and barrier layers, each having a thickness of 5˜300 Å, with a total thickness of 1˜500 nm. The well layers and the barrier layers are both made of AlₚIn_{q}Ga_{1-p-q}N (p, q≧0, 0≦p+q≦1) compound semiconductor doped with Si or Ge, but with different compositions and with the barrier layers having a higher bandgap than that of the well layers. The carrier supply layer should have an electron concentration of 1×10¹⁷˜5×10²¹/cm³.

The configuration of the carrier supply layer has a number of advantages. First, additional electrons are provided into the MQW light emitting layer for recombination with the holes, achieving higher internal quantum efficiency and therefore higher brightness of the proposed LED structure. In addition, as the mobility of the electrons is known to be better than that of the holes, the configuration of the carrier supply layer could slow down the electrons so that they have higher opportunity to recombine with the holes, thereby achieving higher recombination efficiency. Further more, the Si or Ge doping in the carrier supply layer effectively reduce the operation voltage of the proposed LED structure without doping the light emitting layer, which in turn contributes to better crystallinity of the light emitting layer.

Another aspect of the present invention is to have a hole blocking layer interposed between the carrier supply layer and the light emitting layer. The hole blocking layer is made of undoped or Si-doped GaN-based material having a larger bandgap than that of the light emitting layer to prevent the holes from traversing into the carrier supply layer and recombining with the electrons there. The hole blocking layer has a thickness of 5 Å˜0.5 μm.

The configuration of the hole blocking layer has some additional advantages. For instance, experiments show that the presence of the hole blocking layer can increase the breakdown voltage and reduce the leakage current of the proposed LED structure. In addition, as V-shaped defects would be formed on the surface of the carrier supply layer after its growth, the hole blocking layer can smooth the surface and the subsequent growth of the light emitting layer can thereby achieve better crystallinity. In some embodiment of the present invention, the hole blocking layer is made of In-doped or In/Si codoped GaN-based material to achieve even better smoothing effect. When In atoms are added, the surface smoothness of the carrier supply layer could be greatly enhanced and the defects and stacking faults of the light emitting layer could be effectively prevented.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a schematic sectional view showing a nitride based MQW LED structure in accordance with a first embodiment of present invention.

FIG. 2 is a schematic sectional view showing a nitride based MQW LED structure in accordance with a second embodiment of present invention.

FIG. 3 is a schematic sectional view showing a nitride based MQW LED device based on the LED structure of FIG. 1.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

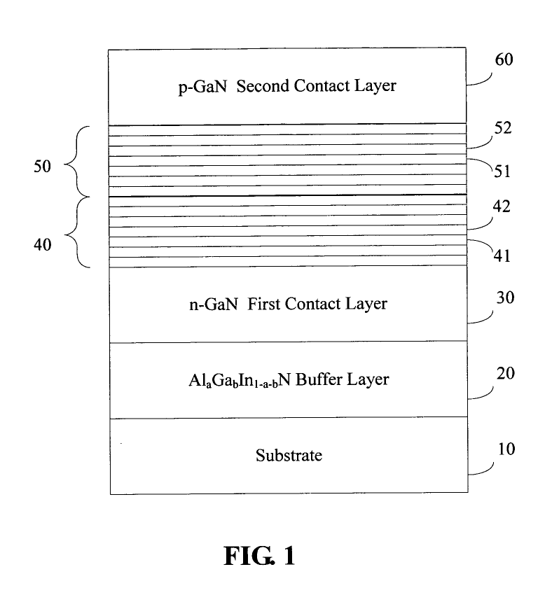

FIG. 1 is a schematic sectional view showing a nitride based MQW LED structure in accordance with a first embodiment of the present invention. Please note that the present specification uses the term ‘LED structure’ to refer to the epitaxial layer structure of a LED, and the term ‘LED device’ to refer to the semiconductor device obtained from forming the electrodes on a LED structure in a subsequent chip process after the formation of the LED structure.

As shown in FIG. 1, at the bottom of the LED structure, the substrate 10 is usually made of aluminum-oxide monocrystalline (sapphire), or an oxide monocrystalline having a lattice constant compatible with that of the epilayers of the LED structure. The substrate 10 can also be made of SiC (6H—SiC or 4H—SiC), Si, ZnO, GaAs, or MgAl₂O₄. Generally, the most common material used for the substrate 10 is sapphire or SiC. On the top side of the substrate 10, a buffer layer 20 made of AlₐGa_{b}In_{1-a-b}N (0≦a, b<1, a+b≦1) is then formed. Please note that, in alternative embodiments, the buffer layer 20 could also be omitted. Please also note that, as common semiconductor manufacturing methods are applied in forming the epilayers of the LED structure which are well known to people skilled in the related arts, their details are generally omitted in the present specification for simplicity sake, unless some specific manufacturing conditions are critical and should be pointed out explicitly.

On top of the buffer layer 20, a first contact layer 30 made of a GaN-based material having a first conduction type is formed. In the present embodiment, the first contact layer 30 is made of an n-typed GaN-based material and, in alternative embodiments, it can also be made of a p-typed GaN-based material. The purpose of having the first contact layer 30 is to provide the required ohmic contact for the subsequent formation of the n-typed electrode in the chip process and to provide a better growing condition for the subsequent epilayers.

In turn, on top of the first contact layer 30, the carrier supply layer 40 is formed by alternately stacking at least two well layers 41 and at least two barrier layers 42. The total thickness of the carrier layer 40 is between 1 nm and 500 nm and each of the well layers 41 and the barrier layers 42 has a thickness between 5 Å and 300 Å. The well layers 41 and the barrier layers 42 are both made of AlₚIn_{q}Ga_{1-p-q}N (p, q≧0, 0≦p+q≦1) compound semiconductor doped with Si or Ge to achieve an electron concentration between 1×10¹⁷/cm³ and 5×10²¹/cm³ for the carrier supply layer 40. The well layers 41 and the barrier layers 42 have different compositions so that the barrier layers 42 have a higher bandgap (Eg) than that of the well layers 41. The well layers 41 and the barrier layers 42 are also formed at different growing temperatures between 600° C. and 1200° C., with the barrier layers 42 grown at a higher temperature.

Then, on top of the carrier supply layer 40, the MQW light emitting layer 50 of the present embodiment is formed by interleaving a plurality of well layers 51 and another plurality of barrier layers 52. The well layers 51 and the barrier layers 52 are both made of undoped AlₓIn_{y}Ga_{1-x-y}N (x, y≧0, 0≦x+y≦1) compound semiconductor, but with different compositions so that the barrier layers 52 have a higher bandgap (Eg) than that of the well layers 51. The well layers 51 and the barrier layers 52 are also formed at different growing temperatures between 600° C. and 1200° C., with the barrier layers 52 grown at a higher temperature. The well layers 41 of the carrier supply layer 40 have appropriate AlₚIn_{q}Ga_{1-p-q}N (p, q≧0, 0≦p+q≦1) compositions so that their bandgap is larger than that of the AlₓIn_{y}Ga_{1-x-y}N (x, y≧0, 0≦x+y≦1) of the light emitting layer 50's well layers 51. Please note that the light emitting layer 50 of the present embodiment is only exemplary and the spirit of the present invention does not require a specific MQW structure for the light emitting layer 50.

The additional electrons from the carrier supply layer 40 are provided into the MQW light emitting layer 50 for recombination with the holes, achieving higher internal quantum efficiency and therefore higher brightness of the proposed LED structure. In addition, as the mobility of the electrons is known to be better than that of the holes, the configuration of the carrier supply layer 40 could also slow down the electrons so that they have higher opportunity to recombine with the holes, thereby achieving higher recombination efficiency. Further more, the Si or Ge doping in the carrier supply layer 40 effectively reduce the operation voltage of the proposed LED structure without doping the light emitting layer 50, which in turn contributes to better crystallinity of the light emitting layer 50.

Finally, on top of the light emitting layer 50, a second contact layer 60 made of a GaN-based material having a second conduction type is formed, which is opposite to the aforementioned first conduction type. In the present embodiment, therefore, the second contact layer 60 is made of a p-typed GaN-based material and, in alternative embodiments, it can also be made of an n-typed GaN-based material. The purpose of having the second contact layer 60 is to provide the required ohmic contact for the subsequent formation of the p-typed electrode in the chip process.

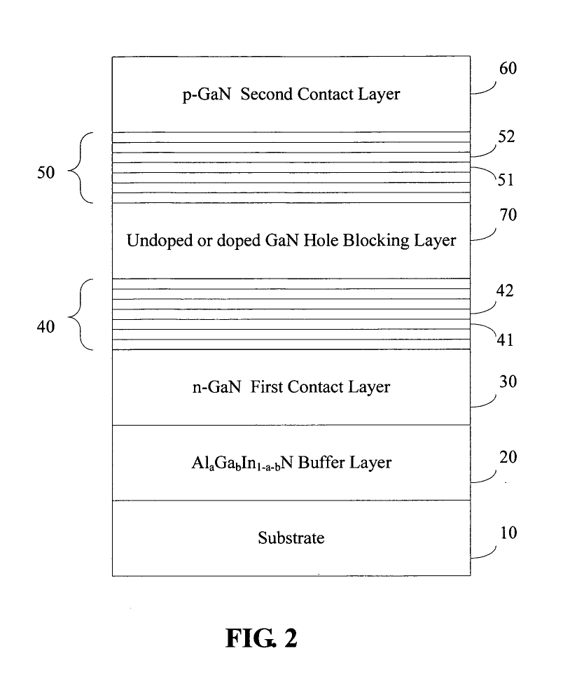

FIG. 2 is a schematic sectional view showing a nitride based MQW LED structure in accordance with a second embodiment of present invention. Basically, the present embodiment is structured similar to the first embodiment and the only difference lies in the configuration of a hole blocking layer 70 interposed between the carrier supply layer 40 and the light emitting layer 50. The two most important reasons for having the hole blocking layer 70 are (1) to prevent the holes of the light emitting layer 50 from traversing into the carrier supply layer 50 and non-radiatively recombining with the electrons there; and (2) to smooth the V-shaped defects formed on the surface of the carrier supply layer 40 after its growth so that the subsequent growth of the light emitting layer 50 can thereby achieve better crystallinity.

As illustrated, the hole blocking layer 70 is formed on top of the carrier supply layer 40 with undoped or Si-doped or In-doped or In/Si codoped GaN-based material up to a thickness between 5 Å˜0.5 μm under a growing temperature between 600° C. and 1200° C. The material for the hole blocking layer 70 is configured such that it has a larger bandgap than that of the light emitting layer 50 to prevent the holes from escaping into the carrier supply layer 40. The purpose of having In-doping is that the surface smoothness of the carrier supply layer 40 could be further enhanced and the defects and stacking faults of the light emitting layer 50 could be effectively prevented. Experiments have shown that the presence of the hole blocking layer 70 has other side benefits such as increasing the breakdown voltage (Vb) and reducing the leakage current (Ir) of the proposed LED structure.

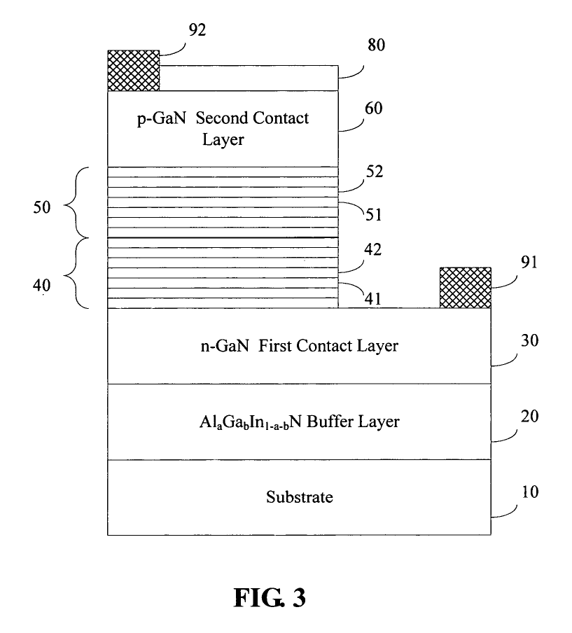

Conventionally, the LED structure shown in FIGS. 1 and 2 is then put through a chip process to form the electrodes and prepare the LED for packaging. FIG. 3 is a schematic sectional view showing a nitride based MQW LED device based on the LED structure of FIG. 1 after the chip process is conducted. Please note that the same process could be applied to the LED structure shown in FIG. 2 as well but, for simplicity, the LED structure of FIG. 1 is used as an example in the following.

The LED structure is first appropriately etched to expose a portion of the top surface of the first contact layer 30. Then, a first electrode 91 made of an appropriate metallic material is formed on top of the exposed area of the first contact layer 30. On the other hand, on top of the second contact layer 60, a transparent conductive layer 80 is formed. The transparent conductive layer 80 can be a metallic conductive layer or a transparent oxide layer. The metallic conductive layer is made of one of the materials including, but not limited to, Ni/Au alloy, Ni/Pt alloy, Ni/Pd alloy, Pd/Au alloy, Pt/Au alloy, Cr/Au alloy, Ni/Au/Be alloy, Ni/Cr/Au alloy, Ni/Pt/Au alloy, and Ni/Pd/Au alloy. The transparent oxide layer, on the other hand, is made of one of the materials including, but not limited to, ITO, CTO, ZnO:Al, ZnGa₂O₄, SnO₂:Sb, Ga₂O₃:Sn, AgInO₂:Sn, In₂O₃:Zn, CuAlO₂, LaCuOS, NiO, CuGaO₂, and SrCu₂O₂. A second electrode 92 is formed on top of the transparent conductive layer 80 or besides the transparent conductive layer 80 as shown in FIG. 3. The second electrode 92 is made of one of the materials including, but not limited to, Ni/Au alloy, Ni/Pt alloy, Ni/Pd alloy, Ni/Co alloy, Pd/Au alloy, Pt/Au alloy, Ti/Au alloy, Cr/Au alloy, Sn/Au alloy, Ta/Au alloy, TiN, TiWNₓ (x≧0), and WSi_{y} (y≧0).

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A nitride-based MQW LED structure, comprising:
a substrate;
a first contact layer made of a GaN-based material having a first conduction type located above said substrate;
a carrier supply layer on top of said first contact layer, said carrier supply layer comprising at least two well layers and at least two barriers alternately stacked upon each other, each of said well layers and said barrier layers being made of a GaN-based material doped with an n-typed impurity, said barrier layers having a higher bandgap than that of said well layers;
a light emitting layer located above said carrier supply layer having a MQW structure of a plurality of well layers and barrier layers each of which is made of a GaN-based material; and
a second contact layer made of a GaN-based material having a second conduction type opposite to said first conduction type on top of said light emitting layer;
wherein said well layers of said carrier supply layer have a higher bandgap than that of said well layers of said light emitting layer.

2. The nitride-based MQW LED structure according to claim 1, further comprising a buffer layer made of a GaN-based material interposed between said substrate and said first contact layer.

3. The nitride-based MQW LED structure according to claim 2, wherein said GaN-based material of said buffer layer is AlₐGa_{b}In_{1-a-b}N (0≦a, b<1, a+b≦1).

4. The nitride-based MQW LED structure according to claim 1, wherein said n-typed impurity of said well layers and said barrier layers of said carrier supply layer is one of Si and Ge.

5. The nitride-based MQW LED structure according to claim 1, wherein each of said well layers and said barrier layers has a thickness between 5 Å and 300 Å.

6. The nitride-based MQW LED structure according to claim 1, wherein said carrier supply layer has a thickness between 1 nm and 500 nm.

7. The nitride-based MQW LED structure according to claim 1, wherein said carrier supply layer has an electron concentration between 1×10¹⁷/cm³ and 5×10²¹/cm³.

8. The nitride-based MQW LED structure according to claim 1, wherein said GaN-based material of said well layers and said barrier layers of said light emitting layer is AlₓIn_{y}Ga_{1-x-y}N (x, y≧0, 0≦x+y≦1).

9. The nitride-based MQW LED structure according to claim 1, wherein said GaN-based material of said well layers and said barrier layers of said light emitting layer is undoped.

10. The nitride-based MQW LED structure according to claim 1, wherein said GaN-based material of said well layers and said barrier layers of said carrier supply layer is AlₚIn_{q}Ga_{1-p-q}N (p, q≧0, 0≦p+q≦1).

11. The nitride-based MQW LED structure according to claim 1, further comprising a hole blocking layer interposed between said carrier supply layer and said light emitting layer, said hole blocking layer being made of a GaN-based material having a larger bandgap than that of said light emitting layer.

12. The nitride-based MQW LED structure according to claim 11, wherein said hole blocking layer has a thickness between 5 Å˜0.5 μm.

13. The nitride-based MQW LED structure according to claim 11, wherein said GaN-based material of said hole blocking layer is undoped.

14. The nitride-based MQW LED structure according to claim 11, wherein said GaN-based material of said hole blocking layer is doped with one of Si, In, and Si/In.

15. A nitride-based MQW LED device, comprising:
a substrate;
a buffer layer made of AlₐGa_{b}In_{1-a-b}N (0≦a, b<1, a+b≦1) on top of said substrate;
a first contact layer made of a GaN-based material having a first conduction type on top of said buffer layer;
a carrier supply layer on top of a part of said first contact layer's top surface, said carrier supply layer comprising at least two well layers and at least two barriers alternately stacked upon each other, each of said well layers and said barrier layers being made of AlₐIn_{b}Ga_{1-p-q}N (p, q≧0, 0≦p+q≦1) doped with an n-typed impurity, said barrier layers having a higher bandgap than that of said well layers;
a first electrode made of an appropriate metallic material on top of another part of said first contact layer's top surface not covered by said carrier supply layer;
a light emitting layer located above said carrier supply layer having a MQW structure of a plurality of well layers and barrier layers each made of AlₓIn_{y}Ga_{1-x-y}N (x, y≧0, 0≦x+y≦1);
a second contact layer made of a GaN-based material having a second conduction type opposite to said first conduction type on top of said light emitting layer;
a transparent conductive layer that is one of a metallic conductive layer and a transparent oxide layer on top of at least a part of the top surface of said second contact layer; and
a second electrode on top of said transparent conductive layer or on top of another part of said second contact layer's top surface not covered by said transparent conductive layer;
wherein said well layers of said carrier supply layer have a higher bandgap than that of said well layers of said light emitting layer.

16. The nitride-based MQW LED device according to claim 15, wherein said n-type impurity of said well layers and said barrier layers of said carrier supply layer is one of Si and Ge.

17. The nitride-based MQW LED device according to claim 15, wherein each of said well layers and said barrier layers has a thickness between 5 Å and 300 Å.

18. The nitride-based MQW LED device according to claim 15, wherein said carrier supply layer has a thickness between 1 nm and 500 nm.

19. The nitride-based MQW LED device according to claim 15, wherein said carrier supply layer has an electron concentration between 1×10¹⁷/cm³ and 5×10²¹/cm³.

20. The nitride-based MQW LED device according to claim 15, wherein said GaN-based material of said well layers and said barrier layers of said light emitting layer is undoped.

21. The nitride-based MQW LED device according to claim 15, further comprising a hole blocking layer interposed between said carrier supply layer and said light emitting layer, said hole blocking layer being made of a GaN-based material having a larger bandgap than that of said light emitting layer.

22. The nitride-based MQW LED structure according to claim 21, wherein said hole blocking layer has a thickness between 5 Å˜0.5 μm.

23. The nitride-based MQW LED device according to claim 21, wherein said GaN-based material of said hole blocking layer is undoped.

24. The nitride-based MQW LED device according to claim 21, wherein said GaN-based material of said hole blocking layer is doped with one of Si, In, and Si/In.

25. The nitride-based MQW LED device according to claim 15, wherein said metallic conductive layer is made of a material selected from the group comprising Ni/Au alloy, Ni/Pt alloy, Ni/Pd alloy, Pd/Au alloy, Pt/Au alloy, Cr/Au alloy, Ni/Au/Be alloy, Ni/Cr/Au alloy, Ni/Pt/Au alloy, and Ni/Pd/Au alloy.

26. The nitride-based MQW LED device according to claim 15, wherein said transparent oxide layer is made of a material selected from the group comprising ITO, CTO, ZnO:Al, ZnGa₂O₄, SnO₂:Sb, Ga₂O₃:Sn, AgInO₂:Sn, In₂O₃:Zn, CuAlO₂, LaCuOS, NiO, CuGaO₂, and SrCu₂O₂.

27. The nitride-based MQW LED device according to claim 15, wherein said second electrode is made of a material selected from the group comprising Ni/Au alloy, Ni/Pt alloy, Ni/Pd alloy, Ni/Co alloy, Pd/Au alloy, Pt/Au alloy, Ti/Au alloy, Cr/Au alloy, Sn/Au alloy, Ta/Au alloy, TiN, TiWNₓ (x≧0), and WSi_{y} (y≧0).
